(19) United States
(12) Patent Application Publication
(10) Pub. No.: US 2008/0150068 A1
(43) Pub. Date: Jun. 26, 2008

(54) Image sensor IC

(76) Inventor: Hiroaki Takasu, Chiba-shi (JP)

Correspondence Address: BRUCE L. ADAMS, ESQ.;ADAMS & WILKS, SUITE 1231, 17 BATTERY PLACE, NEW YORK, NY, 10004, US

(21) Appl. No.: 12/004,152

(22) Filed: Dec. 19, 2007

(30) Foreign Application Priority Data
Dec. 20, 2006 (JP) 2006-342747

(51) Int. Cl. H01L 31/0232

(52) U.S. Cl. 257/440; 257/E31.127

(57) ABSTRACT

Polycrystalline silicon thin films are each fixed to the same potential and are each formed under the protective film of each of a plurality of pixel regions for receiving red light, a plurality of pixel regions for receiving green light, and a plurality of pixel regions for receiving blue light, and each polycrystalline silicon thin films has a different thickness for selectively transmitting a received light wavelength of each of the plurality of pixel regions for receiving red light, the plurality of pixel regions for receiving green light, and the plurality of pixel regions for receiving blue light to function as a color filter. The color filter can be formed during an IC manufacturing process while the color filter is positioned to align with the pixel region serving as a light receiving element, with higher precision.

### BACKGROUND OF THE INVENTION

1. Field of the Invention

The present invention relates to an image sensor IC (integrated circuit) used in a device for capturing and transmitting image information, such as a facsimile, an image scanner, and an electronic camera.

2. Description of the Related Art

FIG. 2 is an exemplary circuit diagram for showing operation of an image sensor of a related art. In a sensor circuit 10 of a MOS image sensor, a reset transistor 11 serving as a switching element for resetting a photodiode 12 to an appropriate voltage, and an amplifier circuit 13 for amplifying light induced charges accumulated in the photodiode 12 are connected to the photodiode 12 including a PN junction.

Optical information can be obtained continuously through following three operations: a reset operation in which the reset transistor 11 is turned on so as to reset the photodiode 12 to a reset voltage to a satisfactory extent; an accumulation operation in which the reset transistor 11 is turned off so as to accumulate light induced charges in the photodiode 12 for a predetermined period of time; and a read operation in which the amplifier circuit 13 is turned on so as to amplify the light induced charges accumulated in the photodiode 12 to read.

Temporal storage of amplified signal may also be performed in the read operation by using a holding circuit 20 including a capacitive element 21 and two switching transistors (22A and 22B). The switching transistor 22A is turned on during the read operation, and the signal is stored in the storage capacitor 21 as an electrical charge by the amplifier circuit 13. The switching transistor 22A is then turned off and the switching transistor 22B is later turned on after an arbitrary holding time, thereby permitting the signal read from the storage capacitor 21.

Separate reading of the signal from the holding circuit in an arbitrary order is also possible after a series of operations, that is, the reset operation, the accumulation operation, and the read operation are collectively performed with respect to a plurality of photodiodes.

In these procedures, photoelectric conversion, whose characteristic is one of most important characteristics in the photodiode, is performed according to an intensity of incident light to the photodiode 12.

In order to improve the photoelectric conversion characteristic, a photoelectric conversion element is disclosed which is capable of suppressing generation of defect in a semiconductor region in which a depletion layer is formed in the photodiode 12 (for example, see JP 2004-312039 A (FIG. 24)).

In the image sensor IC having a plurality of pixels arranged in one IC chip, however, a problem arises in variation of the photoelectric conversion characteristic due to change in intensity of incident light caused by a variation in thickness of a protective film formed on top of each of the plurality of photodiodes 12 which forms the pixels.

Though countermeasure for the problem is proposed in which planalization is performed after formation of the protective film, and in which a second protective film is formed to obtain further uniformity in the film thickness, problems still remain in that, for example, the number of process steps increases, which results in an increase in manufacturing costs, and sufficient uniformity cannot still be obtained. Further, when the image sensor IC is used as a color image sensor, a color filter for selectively transmitting light of each color of red, green, and blue is generally formed to align with a light receiving element in an assembly process after an IC manufacturing process. The process is, however, complicated, and it is difficult to have correct alignment of the color filter with a pixel region serving as the light receiving element, with high precision. Accordingly, further miniaturization and higher definition are hindered.

### SUMMARY OF THE INVENTION

In order to solve the above-mentioned problems, the present invention provides an image sensor with the following structure.

The image sensor IC, which has devices including a photodiode and a transistor formed on the same silicon substrate, includes: a plurality of pixel regions for receiving red light, each of which is formed of the photodiode; a plurality of pixel regions for receiving green light, each of which is formed of the photodiode; a plurality of pixel regions for receiving blue light, each of which is formed of the photodiode; and polycrystalline silicon thin films which are each fixed to the same potential and are each formed on a lower surface of a protective film of each of the plurality of pixel regions for receiving red light, the plurality of pixel regions for receiving green light, and the plurality of pixel regions for receiving blue light, in which the polycrystalline silicon thin films, which are each formed on the plurality of pixel regions for receiving red light, the plurality of pixel regions for receiving green light, and the plurality of pixel regions for receiving blue light, each have a different thickness for selectively transmitting a received light wavelength of each of the plurality of pixel regions for receiving red light, the plurality of pixel regions for receiving green light, and the plurality of pixel regions for receiving blue light.

Since the potential of regions which become a base substrate at the time of the protective film formation can be set substantially constant over the entire pixel regions with the above-mentioned measures, formation speed and film quality of the protective film formed on each of the pixels can be kept constant, whereby the protective film formed on each of the pixels has a substantially uniform film thickness and film quality. Accordingly, the intensity of incident light on the photodiode of each of the pixels can be kept constant, thereby suppressing the variation in a photoelectric conversion characteristic of the pixels, and obtaining an image sensor IC having the uniform photoelectric conversion characteristic over the entire IC.

Further, the polycrystalline silicon thin films formed on each of the pixel region for receiving red light, the pixel region for receiving green light, and the pixel region for receiving blue light, each have a different thickness for selectively transmitting a received light wavelength of each of the pixel region for receiving red light, the pixel region for receiving green light, and the pixel region for receiving blue light. Accordingly, the pixel regions each substantially function as a color filter for transmitting light of each color of red, green, and blue. As a result, the color filter which has to be conventionally formed in a separate assembly process or the like after the IC manufacturing process can be formed during the IC manufacturing process while the color filter is positioned to align with the pixel region serving as the light receiving element, with higher precision. Consequently, a fine and high-definition color image sensor IC can be easily provided.

### BRIEF DESCRIPTION OF THE DRAWINGS

In the accompanying drawings:

FIG. 1 is a schematic top view showing pixel regions of an image sensor according to an embodiment of the present invention; and

FIG. 2 is a circuit diagram illustrating an operation of an image sensor of a related art.

### DETAILED DESCRIPTION OF THE PREFERRED EMBODIMENTS

Preferred embodiments of the present invention will be described with reference to the accompanying drawings.

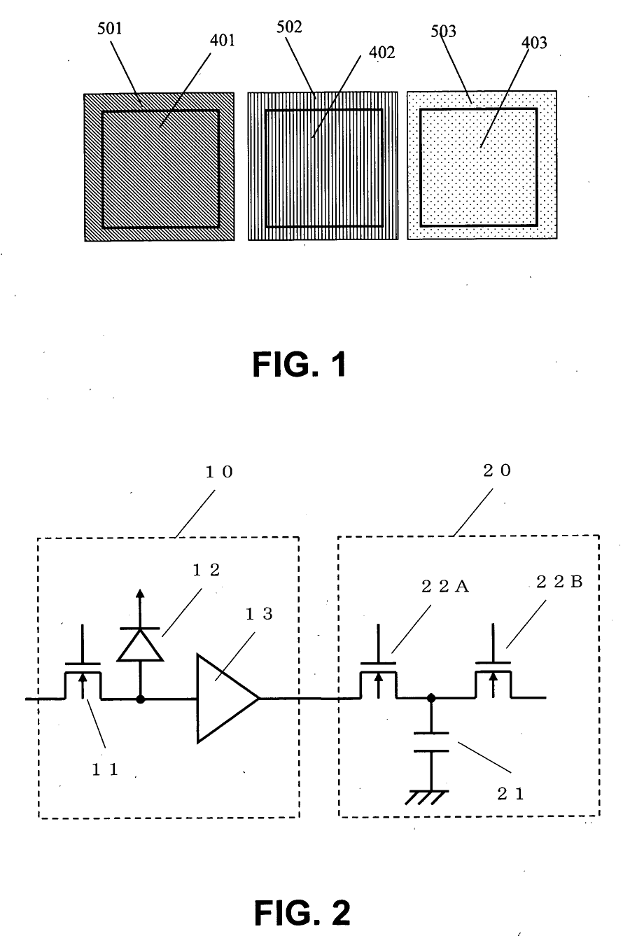

FIG. 1 is a schematic top view showing pixel regions of an image sensor according to the present invention.

A pixel region 401 for receiving red light, a pixel region 402 for receiving green light, and a pixel region 403 for receiving blue light are formed to be adjacent to each other. On the pixel region 401 for receiving red light, there is formed a polycrystalline silicon thin film 501 having a thickness for selectively transmitting red light. On the pixel region 402 for receiving green light, there is formed a polycrystalline silicon thin film 502 having a thickness for selectively transmitting green light. On the pixel region 403 for receiving blue light, there is formed a polycrystalline silicon thin film 503 having a thickness for selectively transmitting blue light. In this case, although not shown in FIG. 1, the polycrystalline silicon thin film 501 having the thickness for selectively transmitting red light, the polycrystalline silicon thin film 502 having the thickness for selectively transmitting green light, and the polycrystalline silicon thin film 503 having the thickness for selectively transmitting blue light are electrically connected to each other and are each fixed to the same potential. In addition, the polycrystalline silicon thin films are electrically connected to each other so as to be held at the same potential as a substrate potential of a silicon substrate for forming the image sensor.

Accordingly, at the time of the protective film formation on the pixel regions thereafter, the potential of the underlying pixel regions can be kept substantially constant over the entire pixel regions in the image sensor IC. As a result, formation speed and film quality of the protective film formed on each of the pixels can be kept constant, whereby the protective film formed on each of the pixels has a substantially uniform film thickness and film quality. Consequently, the intensity of light incident on the photodiode of each of the pixels can be kept constant, thereby suppressing the variation in the photoelectric conversion characteristic of the pixels, and obtaining an image sensor IC having the uniform photoelectric conversion characteristic over the entire IC.

Further, the polycrystalline silicon thin films formed on each of the pixel region 401 for receiving red light, the pixel region 402 for receiving green light, and the pixel region 403 for receiving blue light, each have a different thickness for selectively transmitting a received light wavelength of each of the pixel region 401 for receiving red light, the pixel region 402 for receiving green light, and the pixel region 403 for receiving blue light. Accordingly, the pixel regions each substantially function as a color filter for transmitting light of each color of red, green; and blue.

As a result, the color filter which is conventionally required to be separately formed in a-mounting process or the like after the IC manufacturing process can be formed during the IC manufacturing process while the color filter is positioned to align with the pixel region serving as the light receiving element, with higher precision. Accordingly, fine color pixels, which are hardly achieved, can be formed. Therefore, a fine and high-precision color image sensor IC can be easily provided.

In FIG. 1, for ease of explanation, there is illustrated only one of each of the pixel region 401 for receiving red light, the pixel region 402 for receiving green light, and the pixel region 403 for receiving blue light. In reality, a plurality of each of the pixel regions is formed.

Further, in FIG. 1, there is illustrated an example where the polycrystalline silicon thin film 501 having the thickness for selectively transmitting red light, the polycrystalline silicon thin film 502 having the thickness for selectively transmitting green light, and the polycrystalline silicon thin film 503 having the thickness for selectively transmitting blue light are each formed as an independent film. Alternatively, the polycrystalline silicon thin film 501 having the thickness for selectively transmitting red light, the polycrystalline silicon thin film 502 having the thickness for selectively transmitting green light, and the polycrystalline silicon thin film 503 having the thickness for selectively transmitting blue light may be each formed as a film having the same composition in a continuous form, and may be processed to be formed as films each having a thickness corresponding to the pixel region 401 for receiving red light, the pixel region 402 for receiving green light, and the pixel region 403 for receiving blue light.

What is claimed is:

1. An image sensor IC having photodiodes and transistors disposed on a silicon substrate, comprising:
a plurality of pixel regions for receiving red light, each of which is formed of one the photodiodes;
a plurality of pixel regions for receiving green light, each of which is formed of one the photodiodes;
a plurality of pixel regions for receiving blue light, each of which is formed of one of the photodiodes; and
polycrystalline silicon thin films, each fixed to the same potential, and each disposed under a protective film of each of the plurality of pixel regions for receiving red light, of the plurality of pixel regions for receiving green light, and of the plurality of pixel regions for receiving blue light, and each disposed on the plurality of pixel regions for receiving red light, on the plurality of pixel regions for receiving green light, and on the plurality of pixel regions for receiving blue light, each having a different thickness for selectively transmitting a received light wavelength of each of the plurality of pixel regions for receiving red light, the plurality of pixel regions for receiving green light, and the plurality of pixel regions for receiving blue light.

2. An image sensor IC according to claim 1, wherein the polycrystalline silicon thin films, which are each formed on the plurality of pixel regions for receiving red light, the plurality of pixel regions for receiving green light, and the plurality of pixel regions for receiving blue light, each comprise a continuous film.

3. An image sensor IC according to claim 1, wherein the polycrystalline silicon thin films, which are each formed on the plurality of pixel regions for receiving red light, the plurality of pixel regions for receiving green light, and the plurality of pixel regions for receiving blue light, each comprise an independent film in terms of shape.

4. An image sensor IC according to claim 3, wherein the polycrystalline silicon thin films, which are each formed on the plurality of pixel regions for receiving red light, the plurality of pixel regions for receiving green light, and the plurality of pixel regions for receiving blue light, are electrically connected to each other so as to be held at the same potential as a potential of the silicon substrate.

5. An image sensor IC according to claim 2, wherein the polycrystalline silicon thin films, which are each formed on the plurality of pixel regions for receiving red light, the plurality of pixel regions for receiving green light, and the plurality of pixel regions for receiving blue light, are electrically connected to each other so as to be held at the same potential as a potential of the silicon substrate.
